(19) United States
(12) Patent Application Publication
(10) Pub. No.: US 2026/0276570 A1
(43) Pub. Date: Sep. 17, 2026

(54) SYSTEM AND METHOD FOR CALIBRATION OF INSPECTION TOOLS

(71) Applicant: ASML Netherlands B.V., Veldhoven (NL)

(72) Inventor: Yongxin WANG, San Ramon, CA (US)

(73) Assignee: ASML Netherlands B.V., Veldhoven (NL)

(21) Appl. No.: 19/469,685

(22) PCT Filed: Mar. 7, 2024
(86) PCT No.: PCT/EP2024/056106

§ 371 Date: Sep. 26, 2025

Related U.S. Application Data
(60) Provisional application No. 63/455,837, filed on Mar. 30, 2023.

(51) Int. Cl. G01N 23/2251; G06T 7/80

(52) U.S. Cl. CPC G01N 23/2251; G06T 7/80; G01N 2223/303; G01N 2223/401; G01N 2223/6116; G06T 2200/28; G06T 2207/10061; G06T 2207/30148

(57) ABSTRACT

Systems, apparatuses, and methods for calibration of inspection tools. Systems, apparatuses, and methods may include, after a replaceable reference sample is affixed to a stage of an imaging system: calibrating a parameter of the imaging system based on a scan of the reference sample by the imaging system; and after calibrating the parameter of the imaging system, scanning a sample, wherein the sample comprises a duplicate of a feature of the reference sample.

### CROSS-REFERENCE TO RELATED APPLICATIONS

This application claims priority of US application 63/455,837 which was filed on Mar. 30, 2023 and which is incorporated herein in its entirety by reference.

### FIELD

The description herein relates to the field of inspection and metrology systems, and more particularly to systems for calibration of inspection and metrology tools.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for calibration of inspection and metrology tools. In some embodiments, systems, non-transitory computer readable mediums, or methods may include, after a replaceable product die is affixed to a stage of an imaging system: calibrating a characteristic of the imaging system based on a scan of the product die by the imaging system; and after calibrating the characteristic of the imaging system, scanning a wafer, wherein the wafer comprises a copy of a feature of the product die.

In some embodiments, systems, non-transitory computer readable mediums, or methods may include, after a replaceable reference sample is affixed to a stage of an imaging system: calibrating a parameter of the imaging system based on a scan of the reference sample by the imaging system; and after calibrating the parameter of the imaging system, scanning a sample, wherein the sample comprises a duplicate of a feature of the reference sample.

In some embodiments, systems, non-transitory computer readable mediums, or methods may include, after a replaceable product die is affixed to a stage of an imaging system: supplying power to one or more pins of the replaceable product die; obtaining a first voltage contrast image of a node of the replaceable product die; varying a control signal associated with the supplied power of one or more of the pins to cause a resistance or a capacitance of the node to be adjusted; obtaining a second voltage contrast image of the node; and calibrating a resistance or a capacitance data measurement based on the first voltage contrast image and the second voltage contrast image and the adjustment.

In some embodiments, systems, non-transitory computer readable mediums, or methods may include, after a product die is affixed to a stage of an imaging system: calibrating a characteristic of the imaging system based on a scan of the product die by the imaging system; and after calibrating the characteristic of the imaging system, scanning a wafer, wherein the wafer comprises a copy of a feature of the product die.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3 is an exemplary graph showing a yield rate of secondary electrons relative to landing energy of primary electron beamlets, consistent with embodiments of the present disclosure.

FIG. 4 is a schematic diagram illustrating an exemplary a voltage contrast response of a wafer, consistent with embodiments of the present disclosure.

FIG. 5 is a schematic diagram of an exemplary charged particle system, consistent with embodiments of the present disclosure.

FIG. 6 shows an exemplary stage of an inspection system, consistent with embodiments of the present disclosure.

FIG. 7A shows an exemplary sample cartridge, consistent with embodiments of the present disclosure.

FIG. 7B shows an exemplary sample cartridge, consistent with embodiments of the present disclosure.

FIG. 8 is a flowchart illustrating an exemplary calibration process, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000 th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly, and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be projected onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may projected more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

Inspection tools may be calibrated and tuned using a reference sample (e.g., a product die on a wafer). Typical systems use general purpose reference samples to calibrate inspection tools. These typical systems, however, suffer from constraints. The reference samples used to calibrate typical systems are fixed to a stage of the inspection tool and are not replaceable without significant hardware modification. Typical configurations with fixed reference samples are undesirable because the patterns and features on the reference samples are often different from, and unrelated to, the patterns and features of samples used during actual inspection. Therefore, typical systems often do not accurately capture the behavior of inspected samples. Additionally, typical systems cannot be easily tuned due to the differences between the reference sample and the inspected samples.

Additionally, a typical sample wafer, which has reference samples, may be used to calibrate the system. However, a wafer under inspection may need to be unloaded from the system before this sample wafer containing reference samples is loaded into the system. Due to the unloading and loading steps, conditions in the main chamber may be changed. Moreover, while some performance drifts in the system are typically slow processes, unloading and loading steps take additional time because they involve venting and pumping the load lock to replace wafers in the system (e.g., a reference wafer or a sample under inspection). As a result, the drift induced error or noise on the reference wafer and on the sample wafer will not be the same. Therefore, the error or noise generating during inspection of a sample wafer cannot be treated as common mode noise and removed from the inspection results. These differences in error or noise between the reference wafer and the sample wafer may cause degradation of the inspection performance of the system.

Moreover, typical systems cannot undergo calibration and simultaneously inspect a sample, thereby leading to increased noise in the measurement of the inspected sample (e.g., noise due to drifting during inspection). Additionally, typical systems are not configured to directly measure performance of the system based on electron beam profiles (e.g., beam spot size, beam spot shape, etc.). Typical systems are also not configured to obtain electrical performance or properties (e.g., resistance, capacitance, inductance, etc.) by generating SEM images of a sample.

Some disclosed embodiments provide systems and methods that address some or all of these disadvantages by calibrating inspection and metrology tools using samples that are replaceably affixed to a stage of the system. For example, the disclosed embodiments may replaceably affix a product die to a stage of an imaging system, calibrate a characteristic of the imaging system based on a scan of the product die by the imaging system, and scan a wafer that includes copy features of the product die. By replaceably affixing a product die to a stage of an imaging system to calibrate a characteristic of the imaging system, the imaging system may use a reference product die with features that are the same as the wafer to be inspected and avoid using a general purpose reference sample. That is, reference samples with patterns and features similar to the inspected sample may be used to calibrate the imaging system.

Moreover, by replaceably affixing the product die to the stage of the imaging system, the imaging system may be calibrated using different product dies as needed without significant hardware modification. As a result, the imaging system may accurately capture the behavior of the inspected samples and easily tune to the differences between the reference sample and the inspected sample.

Additionally, the disclosed embodiments provide systems and methods where the reference sample and the inspected sample may be simultaneously positioned on a stage of the imaging system. By providing systems and methods where the reference sample and the inspected sample may be simultaneously positioned on a stage of the imaging system, a wafer under inspection does not necessarily need to be unloaded from the system before a sample wafer containing reference samples is loaded into the system. By reducing the unloading and loading steps, conditions in the main chamber may not change significantly. As a result, the drift induced error or noise on the reference wafer and on the sample wafer may be substantially the same. Therefore, the error or noise generating during inspection of a sample wafer may be treated as common mode noise and removed from the inspection results. Moreover, the reduction in differences in error or noise between the reference wafer and the sample wafer may reduce degradation of the inspection performance of the system.

Moreover, by replaceably affixing product dies to the stage of the system, the disclosed embodiments may be configured to directly measure or obtain the electrical performance or properties of the system and the sample.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

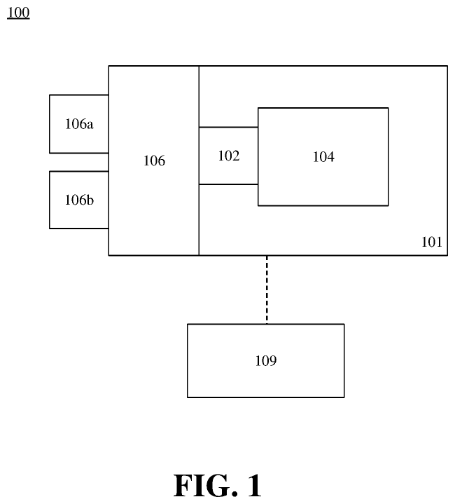

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

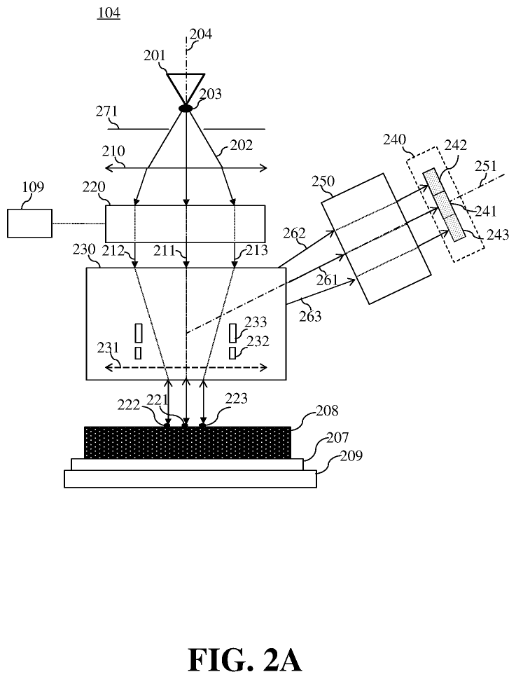

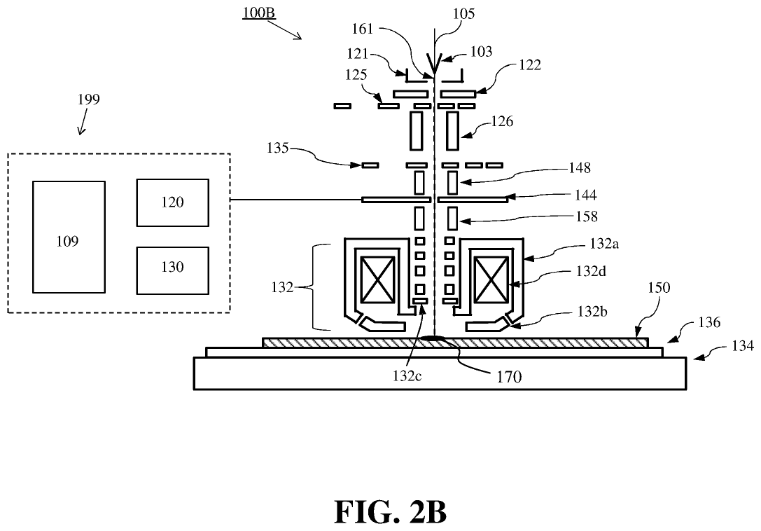

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principal plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

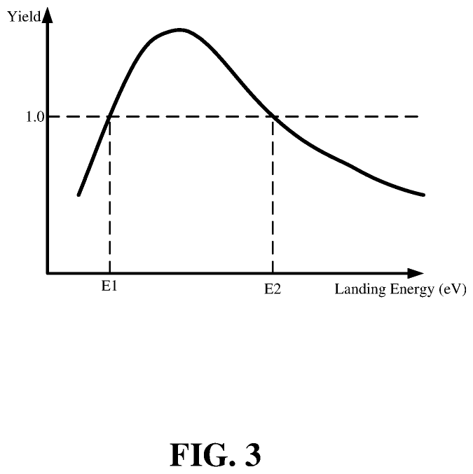

FIG. 3 illustrates an exemplary graph showing a yield rate of secondary electrons relative to landing energy of primary electron beamlets, consistent with embodiments of the present disclosure. The graph illustrates the relationship of the landing energy of a plurality of beamlets of a primary electron beam (e.g., plurality of beamlets 211, 212, or 213 of primary electron beam 202 of FIG. 2A; electron beam 161 of FIG. 2B) and the yield rate of secondary electron beams (e.g., secondary electron beams 261, 262, or 263 of FIG. 2A). The yield rate indicates the number of secondary electrons that are produced in response to the impact of the primary electrons. For example, a yield rate greater than 1.0 indicates that more secondary electrons may be produced than the number of primary electrons that have landed on the wafer. Similarly, a yield rate of less than 1.0 indicates that fewer secondary electrons may be produced in response to the impact of the primary electrons.

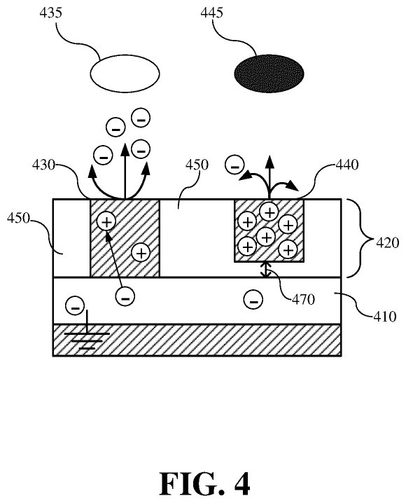

As shown in the graph of FIG. 3, when the landing energy of the primary electrons is within a range from E₁ to E₂, more electrons may leave the surface of the wafer than land onto the surface of the wafer, which may result in a positive electrical potential at the surface of the wafer. In some embodiments, defect inspection may be performed in the foregoing range of landing energies, which is called “positive mode.” An electron beam tool (e.g., electron beam tool 104 of FIG. 2A; electron beam tool 100B of FIG. 2B) may generate a darker voltage contrast image of a device structure with a more positive surface potential since a detection device (e.g., detection device 240 of FIG. 2A; detector 144 of FIG. 2B) may receive fewer secondary electrons (see FIG. 4).

When the landing energy is lower than E₁ or higher than E₂, fewer electrons may leave the surface of the wafer, thereby resulting in a negative electrical potential at the surface of the wafer. In some embodiments, defect inspection may be performed in this range of the landing energies, which is called “negative mode.” An electron beam tool (e.g., electron beam tool 104 of FIG. 2A; electron beam tool 100B of FIG. 2B) may generate a brighter voltage contrast image of a device structure with a more negative surface potential a detection device (e.g., detection device 240 of FIG. 2A; detector 144 of FIG. 2B) may receive more secondary electrons (see FIG. 4).

In some embodiments, the landing energy of the primary electron beams may be controlled by the total bias between the electron source and the wafer.

FIG. 4 illustrates a schematic diagram of a voltage contrast response of a wafer, consistent with embodiments of the present disclosure. In some embodiments, physical and electrical defects in a wafer (e.g., resistive shorts and opens, defects in deep trench capacitors, back end of line (BEOL) defects, etc.) can be detected using a voltage contrast method of a charged particle inspection system. Defect detection using voltage contrast images may use a pre-scanning process (i.e., a charging, flooding, neutralization, or prepping process), where charged particles are applied to an area of the wafer (e.g., sample 208 of FIG. 2A; wafer 150 of FIG. 2B) to be inspected before conducting the inspection.

In some embodiments, an electron beam tool (e.g., electron beam tool 104 of FIG. 2A; electron beam tool 100B of FIG. 2B) may be used to detect defects in internal or external structures of a wafer by illuminating the wafer with a plurality of beamlets of a primary electron beam (e.g., plurality of beamlets 211, 212, or 213 of primary electron beam 202 of FIG. 2A; electron beam 161 of FIG. 2B) and measuring a voltage contrast response of the wafer to the illumination. In some embodiments, the wafer may comprise a test device region 420 that is developed on a substrate 410. In some embodiments, test device region 420 may include multiple device structures 430 and 440 separated by insulating material 450. For example, device structure 430 is connected to substrate 410. In contrast, device structure 440 is separated from substrate 410 by insulating material 450 such that a thin insulator structure 470 (e.g., thin oxide) exists between device structure 440 and substrate 410.

The electron beam tool may generate secondary electrons (e.g., secondary electron beams 261, 262, or 263 of FIG. 2A) from the surface of test device region 420 by scanning the surface of test device region 420 with a plurality of beamlets of a primary electron beam. As explained above, when the landing energy of the primary electrons is between E₁ and E₂ (i.e., the yield rate is greater than 1.0 in FIG. 3), more electrons may leave the surface of the wafer than land on the surface, thereby resulting in a positive electrical potential at the surface of the wafer.

As shown in FIG. 4, a positive electrical potential may build-up at the surface of a wafer. For example, after an electron beam tool scans test device region 420 (e.g., during a pre-scanning process), device structure 440 may retain more positive charges because device structure 440 is not connected to an electrical ground in substrate 410, thereby resulting in a positive electrical potential at the surface of device structure 440. In contrast, primary electrons with the same landing energy (i.e., the same yield rate) applied to device structure 430 may result in fewer positive charges retained in device structure 430 since positive charges may be neutralized by electrons supplied by the connection to substrate 410.

An image processing system (e.g., controller 109 of FIG. 2A; controller 109 of FIG. 2B) of an electron beam tool may generate voltage contrast images 435 and 445 of corresponding device structures 430 and 440, respectively. For example, device structure 430 is shorted to the ground and may not retain built-up positive charges. Accordingly, when primary electron beamlets land on the surface of the wafer during inspection, device structure 430 may repel more secondary electrons thereby resulting in a brighter voltage contrast image. In contrast, because device structure 440 has no connection to substrate 410 or any other grounds, device structure 440 may retain a build-up of positive charges. This build-up of positive charges may cause device structure 440 to repel fewer secondary electrons during inspection, thereby resulting in a darker voltage contrast image.

An electron beam tool (e.g., multi-beam electron beam tool 104 of FIG. 2A; electron beam tool 100B of FIG. 2B) may pre-scan the surface of a wafer by supplying electrons to build up the electrical potential on the surface of the wafer. After pre-scanning the wafer, the electron beam tool may obtain images of multiple dies within the wafer. Pre-scanning is applied to the wafer under the assumption that the electrical surface potential built-up on the surface of the wafer during pre-scanning will be retained during inspection and will remain above the detection threshold of the electron beam tool.

However, the built-up surface potential level may change during inspection due to the effects of electrical breakdown or tunneling, thereby resulting in failure to detect defects. For example, when a high voltage is applied to a high resistance thin device structure (e.g., thin oxide), such as an insulator structure 470, leakage current may flow through the high resistance structure, thereby preventing the structure from functioning as a perfect insulator. This may affect circuit functionality and result in a device defect. A similar effect of leakage current may also occur in a structure with improperly formed materials or a high resistance metal layer, for example a cobalt silicide (e.g., CoSi, CoSi₂, Co₂Si, Co₃Si, etc.) layer between a tungsten plug and a source or drain area of a field-effect transistor (FET).

A defective etching process may leave a thin oxide resulting in unwanted electrical blockage (e.g., open circuit) between two structures (e.g., device structure 440 and substrate 410) intended to be electrically connected. For example, device structures 430 and 440 may be designed to make contact with substrate 410 and function identically, but due to manufacturing errors, insulator structure 470 may exist in device structure 440. In this case, insulator structure 470 may represent a defect susceptible to a breakdown effect.

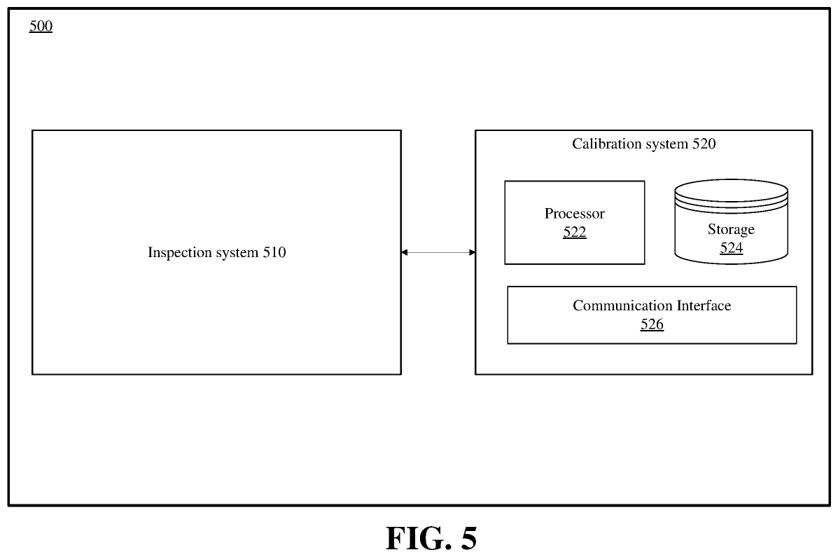

Reference is now made to FIG. 5, a schematic diagram of an exemplary charged particle system 500, consistent with embodiments of the present disclosure. Charged particle system 500 may include an inspection system 510 and a calibration system 520. While an inspection system 510 is shown and described for purposes of simplicity, it is appreciated that a metrology system can also be used.

Inspection system 510 and calibration system 520 may be electrically coupled (directly or indirectly) to each other, either physically (e.g., by a cable) or remotely. Inspection system 510 may be the system (e.g., an imaging system) described with respect to FIGS. 1, 2A, and 2B, used to acquire images of a wafer (see, e.g., sample 208 of FIG. 2A, wafer 150 of FIG. 2B). In some embodiments, calibration system 520 may be a part of inspection system 510. In some embodiments, calibration system 520 may be a part of a controller (e.g., controller 109).

Calibration system 520 may include one or more processors (e.g., processor 522, an instance of which is used for purposes of simplicity) and a storage 524. The one or more processors can include a generic or specific electronic device capable of manipulating or processing information. For example, the one or more processors may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

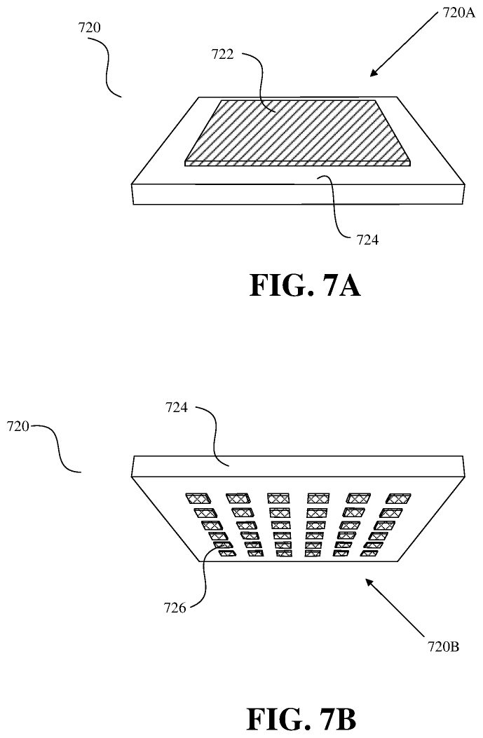

In some embodiments, inspection system 510 may include a product die (e.g., sample die 722 of FIG. 7A) of a wafer that is replaceably affixed to a stage (e.g., motorized stage 209 of FIG. 2A; motorized stage 134 of FIG. 2B) of inspection system 510. In some embodiments, “replaceably” may mean that the product die may be exchanged for another product die in the system. That is, a first product die may be affixed to a stage, the first product die may be removed from the stage, and a second product die may be affixed to the stage. It should be understood that the disclosed embodiments are not limited to two product dies affixed to or removed from the stage, and that any number of product dies may be affixed to or removed from the stage. In some embodiments, “replaceably” may mean that the product die is not permanently fixed to the stage. In some embodiments, the product die may be a reference product die (e.g., reference sample). In some embodiments, the product die may be an inspection product die to be inspected.

In some embodiments, inspection system 510 may generate at least one image of the product die by scanning the product die (e.g., using EBI system 100 of FIG. 1; using e-beam tool 104 of FIG. 2A; using e-beam tool 100B of FIG. 2B). In some embodiments, the generated image may include features (e.g., line patterns, contacts, etc.) of the product die.

Calibration system 520 may include a communication interface 526 to receive and send data to inspection system 510. Processor 522 may be configured to receive one or more images of a sample (e.g., a reference sample) from inspection system 510. In some embodiments, calibration system 520 may calibrate a characteristic (e.g., software parameter, hardware parameter, etc.) of inspection system 510 based on a scan of the product die (e.g., a reference product die). In some embodiments, calibration system 520 may automatically calibrate a characteristic of inspection system 510 based on a scan of the product die. For example, a reference product die may comprise copy (e.g., duplicate) features of an inspection product die that will be inspected. That is, the inspection product die may be manufactured by the same process as the reference product die or may have the same feature profiles as the reference product die (e.g., the reference product die and the inspection product die may have the same metal thickness, same pitches, same materials, etc.). Advantageously, the reference product die may be replaceably affixed to a stage such that the reference product die may be exchanged for another reference product die, so that the inspection product die to be inspected after calibration comprises copy features of the reference product die. This configuration allows inspection system 510 to be easily tuned and for inspection measurements of the inspected product die to accurately characterize the inspected product die.

In some embodiments, calibration system 520 may calibrate a characteristic of inspection system 510 based on a feature of the reference product die by extracting feature profiles (e.g., dimension of a feature, shape of a feature, boundaries of a feature, etc.) from the image of the reference product die.

In some embodiments, calibration system 520 may calibrate software of inspection system 510 by adjusting or tuning the software settings to adjust the image generated by the scan of the product die. In some embodiments, calibration system 520 may automatically calibrate software of inspection system 510 by automatically adjusting or tuning the software settings to adjust the image generated by the scan of the product die. For example, calibration system 520 may automatically compare the extracted feature profiles of the reference product die to the actual feature profiles (e.g., feature profiles of the reference product die that are known or determined) of the reference product die and adjust the software such that the image of the reference product die is adjusted to characterize the reference product die accurately.

In some embodiments, calibration system 520 may automatically calibrate hardware of inspection system 510 by automatically adjusting or tuning settings of the hardware settings (e.g., settings related to FOV, magnification, deflectors, beam profile, etc.) to adjust the image generated by the scan of the product die. For example, calibration system 520 may compare the extracted feature profiles of the reference product die to the actual feature profiles (e.g., feature profiles of the reference product die that are known or determined) of the reference product die and automatically adjust the hardware such that images of the reference product die (that are generated after calibration) characterize the reference product die accurately.

In some embodiments, scanning the reference product die may include generating a first image of a node of the reference product die and generating a second image of the node of the reference product die. In some embodiments, inspection system 510 may be configured to connect a pin of the reference product die to a power supply (e.g., by electrical contact 726 of FIG. 7B). That is, inspection system 510 may be configured to supply power to a pin of the reference product die. In some embodiments, inspection system 510 may generate the first image of the node of the reference product die, vary a control signal to vary a current or a voltage of the pin to cause a characteristic of the node to be adjusted, and generate the second image of the node of the reference product die. In some embodiments, a current of the pin may be measured when a voltage is applied to the pin. In some embodiments, a voltage of the pin may be measured when a current is applied to the pin. In some embodiments, a current and a voltage may be measured on the same pin. In some embodiments, a current may be measured on a first pin and a voltage may be measured on a second pin, different from the first pin. In some embodiments, calibration system 520 may calibrate a characteristic of inspection system 510 based on the first image, the second image, and the adjusted characteristic of the node.

In some embodiments, calibration system 520 may calibrate inspection system 510 to increase the accuracy, resolution, and repeatability of certain measurements, such as those described in WO 2022053491 A1, which is incorporated in its entirety. In some embodiments, the first image and the second image may be grey scale images (e.g., voltage contrast images). In some embodiments, the characteristic of the node that is adjusted during calibration may be at least one of a resistance, capacitance, or inductance of the node. For example, calibration system 520 may determine a relationship between the generated voltage contrast images of the node and the corresponding characteristic (e.g., resistance, capacitance, inductance, etc.) of the node. Calibration system 520 may calibrate inspection system 510 by automatically adjusting hardware (e.g., settings related to FOV, magnification, deflectors, beam profile, etc.) of inspection system 510 based on a comparison of the measured characteristic of the node and the actual characteristic (e.g., the known or determined resistance, capacitance, inductance, etc.) of the node.

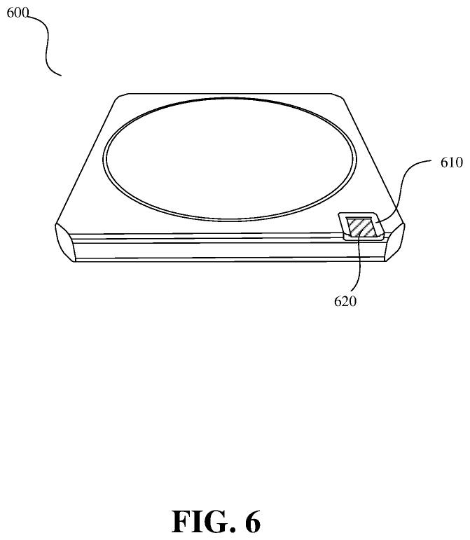

In some embodiments, calibration system 520 may determine a relationship between the generated voltage contrast images of the node and the corresponding characteristic of the node by varying a control signal to vary a current or a voltage of the pin while the reference product die is in sample cartridge holder (e.g., sample cartridge holder 610 of FIG. 6) on a stage (e.g., motorized stage 209 of FIG. 2A; motorized stage 134 of FIG. 2B; stage 600 of FIG. 6). In some embodiments, calibration system 520 may determine a relationship between the generated voltage contrast images of the node and the corresponding characteristic of the node using lab results of the characteristic of the node. For example, instead of varying a current or a voltage of a reference product die while the reference product die is in a sample cartridge holder, a current or a voltage of a reference product die may be varied on a lab bench. A relationship between the generated voltage contrast images of the node and the corresponding characteristic of the node may be determined using the results from the lab bench and used to calibrate inspection system 510.

As described above, the inspected product die may comprise copy features of the reference product die used for calibration. After calibration, inspection system 510 may generate voltage contrast images of the inspection product die and determine characteristics (e.g., resistance, capacitance, inductance, etc.) of nodes or other features of the inspection product die based on the voltage contrast images (e.g., based on the determined relationship between the voltage contrast images and corresponding node characteristic). In some embodiments, the above-described calibration and configurations may increase the accuracy, resolution, and repeatability of data obtained using techniques described in WO 2022053491 A1.

In some embodiments, calibration system 520 may calibrate inspection system 510 by obtaining a signal from the reference product die (e.g., by electrical contact 726 of FIG. 7B) associated with a scan of the reference product die, determine a relationship between the signal and a beam profile (e.g., beam spot size, beam spot shape, etc.) associated with the signal (e.g., based on known beam profiles), and automatically adjust hardware (e.g., settings related to FOV, magnification, deflectors, beam profile, etc.) of inspection system 510 to adjust the beam profile.

In some embodiments, a sample cartridge holder (e.g., sample cartridge holder 610 of FIG. 6) used to hold the reference product die may be designed to be capable of measuring beam profile data associated with a scan of the reference product die. In some embodiments, a sample cartridge holder may be designed to be capable of measuring beam profile data associated with a scan of the reference product die based on features of the reference product die that are the same as features on the inspection product die.

As described above, inspection system 510 may inspect an inspection product die that comprises copy features of the reference product die after calibration of inspection system 510. In some embodiments, inspection system 510 may obtain a signal from the inspection product die associated with a scan of the inspection product die and determine a beam profile associated with the signal based on the determined relationship between signals and beam profiles. Advantageously, inspection system 510 may directly measure its performance using signals from inspected product dies to determine electron beam profiles during inspection.

In some embodiments, inspection system 510 may undergo calibration using a reference product die and simultaneously inspect an inspection product die, thereby leading to reduced noise in the measurement of the inspected product die (e.g., reduced noise due to drifting during inspection).

Advantageously, inspection system 510 may be tuned, calibrated, and aligned for specific product dies, resulting in improved performance during inspection of product dies. Inspection tool-to-tool performance matching may also improve since all tools may be aligned within a narrow range of performance for a specific product die, rather than using a general purpose sample to calibrate all tools to meet a wide range of performance.

During inspection, a reference sample may be used to check and track the performance drift of the tool and perform real-time corrections to ensure high performance and tool-to-tool matching. Since both the reference sample and the inspection sample may be in the system chamber and on the same stage and may have the same features in the areas of interest, the drift in the system will have similar effects on the SEM images of the two samples. Thus, the drift between the reference sample and the inspection sample may be treated as a common mode interference and may be canceled out by continuous correction by calibration system 520.

Reference is now made to FIG. 6, an exemplary stage 600 (e.g., motorized stage 209 of FIG. 2A; motorized stage 134 of FIG. 2B) of an inspection system (e.g., systems described with respect to FIGS. 1, 2A, 2B, and 5), consistent with embodiments of the present disclosure.

In some embodiments, stage 600 may include a sample cartridge holder 610, which may hold a sample cartridge 620 (see, e.g., sample 208 of FIG. 2A, wafer 150 of FIG. 2B). In some embodiments, sample cartridge 620 may include a product die (e.g., sample die 722 of FIG. 7A) of a wafer that is replaceably affixed to stage 600. In some embodiments, “replaceably” may mean that the product die may be exchanged for another product die in the system. That is, a first product die may be affixed to a stage, the first product die may be removed from the stage, and a second product die may be affixed to the stage. It should be understood that the disclosed embodiments are not limited to two product dies affixed to or removed from the stage, and that any number of product dies may be affixed to or removed from the stage. In some embodiments, “replaceably” may mean that the product die is not permanently fixed to stage 600 or sample cartridge holder 610. In some embodiments, the product die may be a reference product die (e.g., reference sample). In some embodiments, the product die may be an inspection product die to be inspected.

Advantageously, a reference product die may be replaceably affixed to stage 600 such that the reference product die may be exchanged for another reference product die, so that the inspection product die to be inspected after calibration comprises copy features of the reference product die. This configuration allows inspection systems to be easily tuned and for inspection measurements of the inspected product die to accurately characterize the inspected product die.

Reference is now made to FIGS. 7A and 7B, an exemplary sample cartridge 720 (e.g., sample cartridge 620 of FIG. 6), consistent with embodiments of the present disclosure.

As shown in FIG. 7A, a front side 720A of sample cartridge 720 may include a sample die 722 on a sample cartridge substrate 724.

As shown in FIG. 7B, a back side 720B of sample cartridge 720 may include electrical contacts 726 on sample cartridge substrate 724.

In some embodiments, an inspection system (e.g., systems described with respect to FIGS. 1, 2A, 2B, and 5) may scan reference product die 722 and generate a first image of a node of reference product die 722 and generate a second image of the node of reference product die 722. In some embodiments, the inspection system may be configured to connect a pin of reference product die 722 to a power supply by electrical contacts 726. That is, the inspection system may be configured to supply power to a pin of reference product die 722. In some embodiments, the inspection system may generate the first image of the node of reference product die 722, vary a control signal to vary a current or a voltage of the pin to cause a characteristic of the node to be adjusted, and generate the second image of the node of reference product die 722. In some embodiments, a current of the pin may be measured when a voltage is applied to the pin. In some embodiments, a voltage of the pin may be measured when a current is applied to the pin. In some embodiments, a current and a voltage may be measured on the same pin. In some embodiments, a current may be measured on a first pin and a voltage may be measured on a second pin, different from the first pin. In some embodiments, a calibration system (e.g., calibration system 520 of FIG. 5) may calibrate a characteristic of the inspection system based on the first image, the second image, and the adjusted characteristic of the node.

In some embodiments, the calibration system may calibrate the inspection system by obtaining a signal from reference product die 722 by electrical contacts 726 associated with a scan of reference product die 722, determine a relationship between the signal and a beam profile (e.g., beam spot size, beam spot shape, etc.) associated with the signal (e.g., based on known beam profiles), and automatically adjust hardware (e.g., settings related to FOV, magnification, deflectors, beam profile, etc.) of the inspection system to adjust the beam profile.

In some embodiments, the inspection system may undergo calibration and simultaneously inspect a sample, thereby leading to reduced noise in the measurement of the inspected sample (e.g., reduced noise due to drifting during inspection).

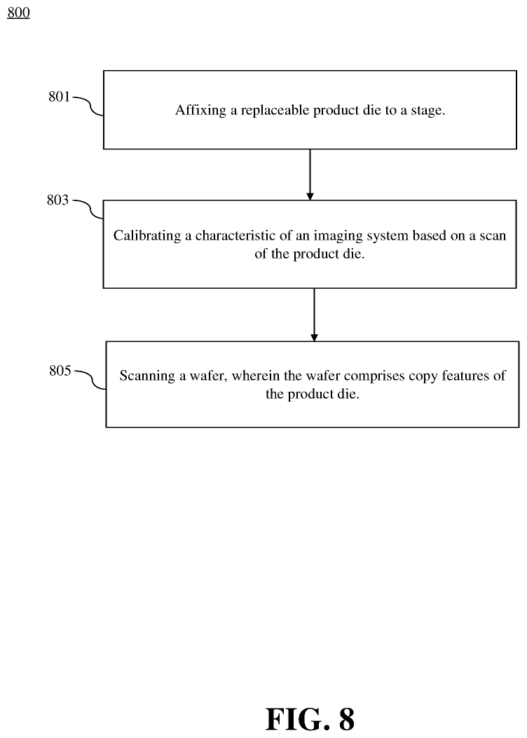

Reference is now made to FIG. 8, illustrating an exemplary calibration process 800, consistent with embodiments of the present disclosure. The steps of method 800 can be performed by a system (e.g., charged particle system 500 of FIG. 5) executing on or otherwise using the features of a computing device (e.g., controller 109 of FIG. 1, charged particle system 500 of FIG. 5, or any components thereof) for purposes of illustration. It is appreciated that the illustrated process 800 can be altered to modify the order of steps and to include additional steps that may be performed by the system.

At step 801, a system may affix a replaceable product die (e.g., sample die 722 of FIG. 7A) of a wafer to a stage (e.g., motorized stage 209 of FIG. 2A; motorized stage 134 of FIG. 2B). In some embodiments, “replaceably” may mean that the product die may be exchanged for another product die in the system. In some embodiments, “replaceably” may mean that the product die is not permanently fixed to the stage. In some embodiments, the product die may be a reference product die (e.g., reference sample). In some embodiments, the product die may be an inspection product die to be inspected.

The system may generate at least one image of the product die by scanning the product die (e.g., using EBI system 100 of FIG. 1; using e-beam tool 104 of FIG. 2A; using e-beam tool 100B of FIG. 2B). In some embodiments, the generated image may include features (e.g., line patterns, contacts, etc.) of the product die.

In some embodiments, scanning the reference product die may include generating a first image of a node of the reference product die and generating a second image of the node of the reference product die. In some embodiments, the system may be configured to connect a pin of the reference product die to a power supply (e.g., by electrical contact 726 of FIG. 7B). That is, the system may be configured to supply power to a pin of the reference product die. In some embodiments, the system may generate the first image of the node of the reference product die, vary a control signal to vary a current or a voltage of the pin to cause a characteristic of the node to be adjusted, and generate the second image of the node of the reference product die. In some embodiments, a current of the pin may be measured when a voltage is applied to the pin. In some embodiments, a voltage of the pin may be measured when a current is applied to the pin. In some embodiments, a current and a voltage may be measured on the same pin. In some embodiments, a current may be measured on a first pin and a voltage may be measured on a second pin, different from the first pin. In some embodiments, the system may calibrate a characteristic of the system based on the first image, the second image, and the adjusted characteristic of the node.

At step 803, the system may calibrate a characteristic (e.g., software parameter, hardware parameter, etc.) of the system based on a scan of the reference product die. In some embodiments, the system may automatically calibrate a characteristic of the system based on a scan of the reference product die.

In some embodiments, the system may calibrate a characteristic of the system based on a feature of the reference product die by extracting feature profiles (e.g., dimension of a feature, shape of a feature, boundaries of a feature, etc.) from the image of the reference product die.

In some embodiments, the system may calibrate software of the system by adjusting the software to adjust the image generated by the scan of the reference product die. In some embodiments, the system may automatically calibrate software of the system by automatically adjusting or tuning the software settings to adjust the image generated by the scan of the product die. For example, the system may automatically compare the extracted feature profiles of the reference product die to the actual feature profiles (e.g., feature profiles of the reference product die that are known or determined) of the reference product die and adjust the software such that the image of the reference product die is adjusted to characterize the reference product die accurately.

In some embodiments, the system may automatically calibrate hardware of the system by automatically adjusting or tuning settings of the hardware (e.g., settings related to FOV, magnification, deflectors, beam profile, etc.) to adjust the image generated by the scan of the reference product die. For example, the system may compare the extracted feature profiles of the reference product die to the actual feature profiles (e.g., feature profiles of the reference product die that are known or determined) of the reference product die and automatically adjust the hardware such that images of the reference product die (that are generated after calibration) characterize the reference product die accurately.

In some embodiments, the system may be calibrated to increase the accuracy, resolution, and repeatability of certain measurements, such as those described in WO 2022053491 A1, which is incorporated in its entirety. In some embodiments, the first image and the second image may be grey scale images (e.g., voltage contrast images). In some embodiments, the characteristic of the node that is adjusted during calibration may be at least one of a resistance, capacitance, or inductance of the node. For example, the system may determine a relationship between the generated voltage contrast images of the node and the corresponding characteristic (e.g., resistance, capacitance, inductance, etc.) of the node. The system may be calibrated by automatically adjusting hardware (e.g., settings related to FOV, magnification, deflectors, beam profile, etc.) of the system based on a comparison of the measured characteristic of the node and the actual characteristic (e.g., the known or determined resistance, capacitance, inductance, etc.) of the node.

As described above, the inspected product die may comprise copy features of the reference product die used for calibration. After calibration, the system may generate voltage contrast images of the inspection product die and determine characteristics (e.g., resistance, capacitance, inductance, etc.) of nodes or other features of the inspection product die based on the voltage contrast images (e.g., based on the determined relationship between the voltage contrast images and corresponding node characteristic). In some embodiments, the above-described calibration and configurations may increase the accuracy, resolution, and repeatability of data obtained using techniques described in WO 2022053491 A1.

In some embodiments, the system may calibrate inspection system 510 by obtaining a signal from the reference product die (e.g., by electrical contact 726 of FIG. 7B) associated with a scan of the reference product die, determine a relationship between the signal and a beam profile (e.g., beam spot size, beam spot shape, etc.) associated with the signal (e.g., based on known beam profiles), and automatically adjust hardware (e.g., settings related to FOV, magnification, deflectors, beam profile, etc.) of the system to adjust the beam profile.

In some embodiments, a sample cartridge holder (e.g., sample cartridge holder 610 of FIG. 6) used to hold the reference product die may be designed to be capable of measuring beam profile data associated with a scan of the reference product die. In some embodiments, a sample cartridge holder may be designed to be capable of measuring beam profile data associated with a scan of the reference product die based on features of the reference product die that are the same as features on the inspection product die.

At step 805, the system may scan a wafer that includes copy features of the product die. The inspection product die may comprise copy (e.g., duplicate) features of the reference product die used to calibrate the system. That is, the inspection product die to be inspected may be manufactured by the same process as the reference product die or may have the same feature profiles as the reference product die (e.g., the reference product dies and the inspection product die may have the same metal thickness, same pitches, same materials, etc.). Advantageously, the reference product die may be replaceably affixed to a stage such that the reference product die may be exchanged for another reference product die, so that the inspection product die to be inspected after calibration comprises copy features of the reference product die. This configuration allows the system to be easily tuned and for inspection measurements of the inspected product die to accurately characterize the product die.

A non-transitory computer readable medium may be provided that stores instructions for a processor of a controller (e.g., controller 109 of FIG. 1) for controlling the electron beam tool or other systems (e.g., charged particle system 500 of FIG. 5) of other systems and servers, or components thereof, consistent with embodiments in the present disclosure. These instructions may allow the one or more processors to carry out calibration, image processing, data processing, beamlet scanning, graphical display, operations of a charged particle beam apparatus, or another imaging device, or the like. In some embodiments, the non-transitory computer readable medium may be provided that stores instructions for a processor to perform the steps of process 800. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method of calibration comprising:
after a replaceable product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.
2. The method of clause 1, further comprising generating an image of the product die based on the scan of the product die, the image comprising the feature of the product die.
3. The method of clause 2, wherein calibrating the characteristic of the imaging system is based on the feature of the product die in the image.
4.The method of any one of clauses 1-3, wherein the characteristic of the imaging system comprises software. 5. The method of clause 4, wherein calibrating the characteristic of the imaging system comprises adjusting a setting of the software of the imaging system to cause an image generated by the scan of the product die to be adjusted.
6.The method of any one of clauses 1-3, wherein the characteristic of the imaging system comprises hardware.
7.The method of clause 6, wherein the calibrating the characteristic of the imaging system comprises adjusting a setting of the hardware of the imaging system to cause an image generated by the scan of the product die to be adjusted.
8.The method of clause 1, wherein:
the scan of the product die enables generation of a first image of a node of the product die and a second image of the node of the product die, and further comprising:
supplying power to a pin of the product die;
obtaining the first image of the node of the product die;
varying a control signal associated with the power supply of the pin to cause a characteristic of the node to be adjusted;
obtaining the second image of the node; and
calibrating the characteristic of the imaging system based on the first image, the second image, and the adjusted characteristic of the node.
9.The method of clause 8, wherein the first image and the second image comprise grey scale images.
10. The method of any one of clauses 8-9, wherein the first image and the second image comprise voltage contrast images.
11. The method of any one of clauses 8-10, wherein the characteristic of the node comprises at least one of a resistance of the node, a capacitance of the node, or an inductance of the node.
12. The method of any one of clauses 8-11, wherein the characteristic of the imaging system comprises at least one of hardware or software.
13. The method of clause 1, wherein calibrating the characteristic of the imaging system comprises: obtaining a signal from the product die associated with the scan;
determining a relationship between the signal and a beam profile associated with the signal; and adjusting hardware of the imaging system to adjust the beam profile.
14. The method of any one of clauses 1-13, wherein the replaceable product die is not permanently fixed to the stage of the imaging system.
15. The method of any one of clauses 1-14, wherein the replaceable product die is a first product die affixed to the stage of the imaging system.
16. The method of clause 15, further comprising:
removing the first product die from the stage of the imaging system; and
affixing a second product die to the stage of the imaging system.
17. A method comprising:
after a replaceable reference sample is affixed to a stage of an imaging system:
calibrating a parameter of the imaging system based on a scan of the reference sample by the imaging system; and
after calibrating the parameter of the imaging system, scanning a sample,
wherein the sample comprises a duplicate of a feature of the reference sample.
18. The method of clause 17, further comprising generating an image of the sample based on the scan of the sample, the image comprising the feature of the sample.
19. The method of clause 18, wherein calibrating the parameter of the imaging system is based on the feature of the sample in the image.
20. The method of any one of clauses 17-19, wherein the parameter of the imaging system comprises software.
21. The method of clause 20, wherein calibrating the parameter of the imaging system comprises adjusting a setting of the software of the imaging system to cause an image generated by the scan of the sample to be adjusted.
22. The method of any one of clauses 17-19, wherein the parameter of the imaging system comprises hardware.
23. The method of clause 22, wherein the calibrating the parameter of the imaging system comprises adjusting a setting of the hardware of the imaging system to cause an image generated by the scan of the sample to be adjusted.
24. The method of clause 17, wherein:
the scan of the sample enables generation of a first image of a node of the sample and a second image of the node of the sample, and further comprising:
supplying power to a pin of the sample;
obtaining the first image of the node of the sample; varying a control signal associated with the power supply of the pin to cause a characteristic of the node to be adjusted;
obtaining the second image of the node; and
calibrating the parameter of the imaging system based on the first image, the second image, and the adjusted characteristic of the node.
25. The method of clause 24, wherein the first image and the second image comprise grey scale images.
26. The method of any one of clauses 24-25, wherein the first image and the second image comprise voltage contrast images.
27. The method of any one of clauses 24-26, wherein the parameter of the node comprises at least one of a resistance of the node, a capacitance of the node, or an inductance of the node.
28. The method of any one of clauses 24-27, wherein the parameter of the imaging system comprises at least one of hardware or software.
29. The method of clause 17, wherein calibrating the parameter of the imaging system comprises:
obtaining a signal from the sample associated with the scan;
determining a relationship between the signal and a beam profile associated with the signal; and adjusting hardware of the imaging system to adjust the beam profile.
30. The method of any one of clauses 17-29, wherein the replaceable reference sample is not permanently fixed to the stage of the imaging system.
31. The method of any one of clauses 17-30, wherein the replaceable reference sample is a first sample affixed to the stage of the imaging system.
32. The method of clause 31, further comprising:
removing the first sample from the stage of the imaging system; and
affixing a second sample to the stage of the imaging system.
33. A method comprising:
after a replaceable product die is affixed to a stage of an imaging system: supplying power to one or more pins of the replaceable product die;
obtaining a first voltage contrast image of a node of the replaceable product die;
varying a control signal associated with the supplied power of one or more of the pins to cause a resistance or a capacitance of the node to be adjusted;
obtaining a second voltage contrast image of the node; and
calibrating a resistance or a capacitance data measurement based on the first voltage contrast image and the second voltage contrast image and the adjustment.
34. The method of clause 33, wherein the replaceable product die is not permanently fixed to the stage of the imaging system.
35. The method of any one of clauses 33-34, wherein the replaceable product die is a first product die affixed to the stage of the imaging system.
36. The method of clause 35, further comprising:
removing the first product die from the stage of the imaging system; and
affixing a second product die to the stage of the imaging system.
37. A method of calibration comprising:
after a product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.
38. The method of clause 37, further comprising generating an image of the product die based on the scan of the product die, the image comprising the feature of the product die.
39. The method of clause 38, wherein calibrating the characteristic of the imaging system is based on the feature of the product die in the image.
40. The method of any one of clauses 37-39, wherein the characteristic of the imaging system comprises software.
41. The method of clause 40, wherein calibrating the characteristic of the imaging system comprises adjusting a setting of the software of the imaging system to cause an image generated by the scan of the product die to be adjusted.
42. The method of any one of clauses 37-39, wherein the characteristic of the imaging system comprises hardware.
43. The method of clause 42, wherein the calibrating the characteristic of the imaging system comprises adjusting a setting of the hardware of the imaging system to cause an image generated by the scan of the product die to be adjusted.
44. The method of clause 37, wherein:
the scan of the product die enables generation of a first image of a node of the product die and a second image of the node of the product die, and further comprising:
supplying power to a pin of the product die;
obtaining the first image of the node of the product die;
varying a control signal associated with the power supply of the pin to cause a characteristic of the node to be adjusted;
obtaining the second image of the node; and
calibrating the characteristic of the imaging system based on the first image, the second image, and the adjusted characteristic of the node.
45. The method of clause 44, wherein the first image and the second image comprise grey scale images.
46. The method of any one of clauses 44-45, wherein the first image and the second image comprise voltage contrast images.
47. The method of any one of clauses 44-46, wherein the characteristic of the node comprises at least one of a resistance of the node, a capacitance of the node, or an inductance of the node.
48. The method of any one of clauses 44-47, wherein the characteristic of the imaging system comprises at least one of hardware or software.
49. The method of clause 37, wherein calibrating the characteristic of the imaging system comprises:
obtaining a signal from the product die associated with the scan;
determining a relationship between the signal and a beam profile associated with the signal; and
adjusting hardware of the imaging system to adjust the beam profile.
50. The method of any one of clauses 37-49, wherein the product die is not permanently fixed to the stage of the imaging system.
51. The method of any one of clauses 37-50, wherein the product die is a first product die affixed to the stage of the imaging system.
52. The method of clause 51, further comprising:
removing the first product die from the stage of the imaging system; and
affixing a second product die to the stage of the imaging system.
53. A system for calibration, the system comprising:
a controller including circuitry configured to cause the system to perform, after a replaceable product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.
54. The system of clause 53, wherein the controller including circuitry is further configured to cause the system to perform generating an image of the product die based on the scan of the product die, the image comprising the feature of the product die.
55. The system of clause 54, wherein calibrating the characteristic of the imaging system is based on the feature of the product die in the image.
56. The system of any one of clauses 53-55, wherein the characteristic of the imaging system comprises software.
57. The system of clause 56, wherein calibrating the characteristic of the imaging system comprises adjusting a setting of the software of the imaging system to cause an image generated by the scan of the product die to be adjusted.
58. The system of any one of clauses 53-55, wherein the characteristic of the imaging system comprises hardware.
59. The system of clause 58, wherein the calibrating the characteristic of the imaging system comprises adjusting a setting of the hardware of the imaging system to cause an image generated by the scan of the product die to be adjusted.
60. The system of clause 53, wherein:
the scan of the product die enables generation of a first image of a node of the product die and a second image of the node of the product die, and further comprising:
supplying power to a pin of the product die;
obtaining the first image of the node of the product die;
varying a control signal associated with the power supply of the pin to cause a characteristic of the node to be adjusted;
obtaining the second image of the node; and
calibrating the characteristic of the imaging system based on the first image, the second image, and the adjusted characteristic of the node.
61. The system of clause 60, wherein the first image and the second image comprise grey scale images.
62. The system of any one of clauses 60-61, wherein the first image and the second image comprise voltage contrast images.
63. The system of any one of clauses 60-62, wherein the characteristic of the node comprises at least one of a resistance of the node, a capacitance of the node, or an inductance of the node.
64. The system of any one of clauses 60-63, wherein the characteristic of the imaging system comprises at least one of hardware or software.
65. The system of clause 53, wherein calibrating the characteristic of the imaging system comprises:
obtaining a signal from the product die associated with the scan;
determining a relationship between the signal and a beam profile associated with the signal; and
adjusting hardware of the imaging system to adjust the beam profile.
66. The system of any one of clauses 53-65, wherein the replaceable product die is not permanently fixed to the stage of the imaging system.
67. The system of any one of clauses 53-66, wherein the replaceable product die is a first product die affixed to the stage of the imaging system.
68. The system of clause 67, wherein the controller including circuitry is further configured to cause the system to perform:
removing the first product die from the stage of the imaging system; and
affixing a second product die to the stage of the imaging system.
69. A system comprising:
a controller including circuitry configured to cause the system to perform, after a replaceable reference sample is affixed to a stage of an imaging system:
calibrating a parameter of the imaging system based on a scan of the reference sample by the imaging system; and
after calibrating the parameter of the imaging system, scanning a sample, wherein the sample comprises a duplicate of a feature of the reference sample.
70. The system of clause 69, wherein the controller including circuitry is further configured to cause the system to perform generating an image of the sample based on the scan of the sample, the image comprising the feature of the sample.
71. The system of clause 70, wherein calibrating the parameter of the imaging system is based on the feature of the sample in the image.
72. The system of any one of clauses 69-71, wherein the parameter of the imaging system comprises software.
73. The system of clause 72, wherein calibrating the parameter of the imaging system comprises adjusting a setting of the software of the imaging system to cause an image generated by the scan of the sample to be adjusted.
74. The system of any one of clauses 69-71, wherein the parameter of the imaging system comprises hardware.
75. The system of clause 74, wherein the calibrating the parameter of the imaging system comprises adjusting a setting of the hardware of the imaging system to cause an image generated by the scan of the sample to be adjusted.
76. The system of clause 69, wherein:
the scan of the sample enables generation of a first image of a node of the sample and a second image of the node of the sample, and further comprising:
supplying power to a pin of the sample;
obtaining the first image of the node of the sample;
varying a control signal associated with the power supply of the pin to cause a characteristic of the node to be adjusted;
obtaining the second image of the node; and
calibrating the parameter of the imaging system based on the first image, the second image, and the adjusted characteristic of the node.
77. The system of clause 76, wherein the first image and the second image comprise grey scale images.
78. The system of any one of clauses 76-77, wherein the first image and the second image comprise voltage contrast images.
79. The system of any one of clauses 76-78, wherein the parameter of the node comprises at least one of a resistance of the node, a capacitance of the node, or an inductance of the node.
80. The system of any one of clauses 76-79, wherein the parameter of the imaging system comprises at least one of hardware or software.
81. The system of clause 69, wherein calibrating the parameter of the imaging system comprises:
obtaining a signal from the sample associated with the scan;
determining a relationship between the signal and a beam profile associated with the signal; and
adjusting hardware of the imaging system to adjust the beam profile.
82. The system of any one of clauses 69-81, wherein the replaceable reference sample is not permanently fixed to the stage of the imaging system.
83. The system of any one of clauses 69-82, wherein the replaceable reference sample is a first sample affixed to the stage of the imaging system.
84. The system of clause 83, wherein the controller including circuitry is further configured to cause the system to perform:
removing the first sample from the stage of the imaging system; and
affixing a second sample to the stage of the imaging system.
85. A system comprising:
a controller including circuitry configured to cause the system to perform, after a replaceable product die is affixed to a stage of an imaging system:
supplying power to one or more pins of the replaceable product die;
obtaining a first voltage contrast image of a node of the replaceable product die;
varying a control signal associated with the supplied power of one or more of the pins to cause a resistance or a capacitance of the node to be adjusted;
obtaining a second voltage contrast image of the node; and
calibrating a resistance or a capacitance data measurement based on the first voltage contrast image and the second voltage contrast image and the adjustment.
86. The system of clause 85, wherein the replaceable product die is not permanently fixed to the stage of the imaging system.
87. The system of any one of clauses 85-86, wherein the replaceable product die is a first product die affixed to the stage of the imaging system.
88. The system of clause 87, wherein the controller including circuitry is further configured to cause the system to perform:
removing the first product die from the stage of the imaging system; and
affixing a second product die to the stage of the imaging system.
89. A system for calibration, the system comprising:
a controller including circuitry configured to cause the system to perform, after a product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.
90. The system of clause 89, wherein the controller including circuitry is further configured to cause the system to perform generating an image of the product die based on the scan of the product die, the image comprising the feature of the product die.
91. The system of clause 90, wherein calibrating the characteristic of the imaging system is based on the feature of the product die in the image.
92. The system of any one of clauses 89-91, wherein the characteristic of the imaging system comprises software.
93. The system of clause 92, wherein calibrating the characteristic of the imaging system comprises adjusting a setting of the software of the imaging system to cause an image generated by the scan of the product die to be adjusted.
94. The system of any one of clauses 89-91, wherein the characteristic of the imaging system comprises hardware.
95. The system of clause 94, wherein the calibrating the characteristic of the imaging system comprises adjusting a setting of the hardware of the imaging system to cause an image generated by the scan of the product die to be adjusted.
96. The system of clause 89, wherein:
the scan of the product die enables generation of a first image of a node of the product die and a second image of the node of the product die, and further comprising:
supplying power to a pin of the product die;
obtaining the first image of the node of the product die;
varying a control signal associated with the power supply of the pin to cause a characteristic of the node to be adjusted;
obtaining the second image of the node; and
calibrating the characteristic of the imaging system based on the first image, the second image, and the adjusted characteristic of the node.
97. The system of clause 96, wherein the first image and the second image comprise grey scale images.
98. The system of any one of clauses 96-97, wherein the first image and the second image comprise voltage contrast images.
99. The system of any one of clauses 96-98, wherein the characteristic of the node comprises at least one of a resistance of the node, a capacitance of the node, or an inductance of the node.
100. The system of any one of clauses 96-99, wherein the characteristic of the imaging system comprises at least one of hardware or software.
101. The system of clause 89, wherein calibrating the characteristic of the imaging system comprises: obtaining a signal from the product die associated with the scan;
determining a relationship between the signal and a beam profile associated with the signal; and
adjusting hardware of the imaging system to adjust the beam profile.
102. The system of any one of clauses 89-101, wherein the product die is not permanently fixed to the stage of the imaging system.
103. The system of any one of clauses 89-102, wherein the product die is a first product die affixed to the stage of the imaging system.
104. The system of clause 103, wherein the controller including circuitry is further configured to cause the system to perform:
removing the first product die from the stage of the imaging system; and
affixing a second product die to the stage of the imaging system.
105. A non-transitory computer readable medium that stores a set of instructions that is executable by at least one processor of a computing device to cause the computing device to perform a method for calibration, the method comprising:
after a replaceable product die is affixed to a stage of an imaging system:
calibrating a characteristic of the imaging system based on a scan of the product die by the imaging system; and
after calibrating the characteristic of the imaging system, scanning a wafer, wherein the wafer comprises a copy of a feature of the product die.
106. The non-transitory computer readable medium of clause 105, wherein the set of instructions that is executable by at least one processor of a computing device to cause the computing device to further perform generating an image of the product die based on the scan of the product die, the image comprising the feature of the product die.
107. The non-transitory computer readable medium of clause 106, wherein calibrating the characteristic of the imaging system is based on the feature of the product die in the image.
108. The non-transitory computer readable medium of any one of clauses 105-107, wherein the characteristic of the imaging system comprises software.
109. The non-transitory computer readable medium of clause 108, wherein calibrating the characteristic of the imaging system comprises adjusting a setting of the software of the imaging system to cause an image generated by the scan of the product die to be adjusted.
110. The non-transitory computer readable medium of any one of clauses 105-107, wherein the characteristic of the imaging system comprises hardware.
111. The non-transitory computer readable medium of clause 110, wherein the calibrating the characteristic of the imaging system comprises adjusting a setting of the hardware of the imaging system to cause an image generated by the scan of the product die to be adjusted.
112. The non-transitory computer readable medium of clause 105, wherein:
the scan of the product die enables generation of a first image of a node of the product die and a second image of the node of the product die, and further comprising:
supplying power to a pin of the product die;
obtaining the first image of the node of the product die;
varying a control signal associated with the power supply of the pin to cause a characteristic of the node to be adjusted;
obtaining the second image of the node; and
calibrating the characteristic of the imaging system based on the first image, the second image, and the adjusted characteristic of the node.
113. The non-transitory computer readable medium of clause 112, wherein the first image and the second image comprise grey scale images.
114. The non-transitory computer readable medium of any one of clauses 112-113, wherein the first image and the second image comprise voltage contrast images.
115. The non-transitory computer readable medium of any one of clauses 112-114, wherein the characteristic of the node comprises at least one of a resistance of the node, a capacitance of the node, or an inductance of the node.
116. The non-transitory computer readable medium of any one of clauses 112-115, wherein the characteristic of the imaging system comprises at least one of hardware or software.
117. The non-transitory computer readable medium of clause 105, wherein calibrating the characteristic of the imaging system comprises:
obtaining a signal from the product die associated with the scan;
determining a relationship between the signal and a beam profile associated with the signal; and adjusting hardware of the imaging system to adjust the beam profile.
118. The non-transitory computer readable medium of any one of clauses 105-117, wherein the replaceable product die is not permanently fixed to the stage of the imaging system.
119. The non-transitory computer readable medium of any one of clauses 105-118, wherein the replaceable product die is a first product die affixed to the stage of the imaging system.
120. The non-transitory computer readable medium of clause 119, wherein the set of instructions that is executable by at least one processor of a computing device to cause the computing device to further perform:
removing the first product die from the stage of the imaging system; and
affixing a second product die to the stage of the imaging system.
121. A non-transitory computer readable medium that stores a set of instructions that is executable by at least one processor of a computing device to cause the computing device to perform a method, the method comprising:
after a replaceable reference sample is affixed to a stage of an imaging system:
calibrating a parameter of the imaging system based on a scan of the reference sample by the imaging system; and
after calibrating the parameter of the imaging system, scanning a sample,
wherein the sample comprises a duplicate of a feature of the reference sample.
122. The non-transitory computer readable medium of clause 121, wherein the set of instructions that is executable by at least one processor of a computing device to cause the computing device to further perform generating an image of the sample based on the scan of the sample, the image comprising the feature of the sample.
123. The non-transitory computer readable medium of clause 122, wherein calibrating the parameter of the imaging system is based on the feature of the sample in the image.
124. The non-transitory computer readable medium of any one of clauses 121-123, wherein the parameter of the imaging system comprises software.
125. The non-transitory computer readable medium of clause 124, wherein calibrating the parameter of the imaging system comprises adjusting a setting of the software of the imaging system to cause an image generated by the scan of the sample to be adjusted.
126. The non-transitory computer readable medium of any one of clauses 121-123, wherein the parameter of the imaging system comprises hardware.
127. The non-transitory computer readable medium of clause 126, wherein the calibrating the parameter of the imaging system comprises adjusting a setting of the hardware of the imaging system to cause an image generated by the scan of the sample to be adjusted.
128. The non-transitory computer readable medium of clause 121, wherein:
the scan of the sample enables generation of a first image of a node of the sample and a second image of the node of the sample, and further comprising:
supplying power to a pin of the sample;
obtaining the first image of the node of the sample; varying a control signal associated with the power supply of the pin to cause a characteristic of the node to be adjusted;
obtaining the second image of the node; and
calibrating the parameter of the imaging system based on the first image, the second image, and the adjusted characteristic of the node.
129. The non-transitory computer readable medium of clause 128, wherein the first image and the second image comprise grey scale images.
130. The non-transitory computer readable medium of any one of clauses 128-129, wherein the first image and the second image comprise voltage contrast images.
131. The non-transitory computer readable medium of any one of clauses 128-130, wherein the parameter of the node comprises at least one of a resistance of the node, a capacitance of the node, or an inductance of the node.
132. The non-transitory computer readable medium of any one of clauses 128-131, wherein the parameter of the imaging system comprises at least one of hardware or software.
133. The non-transitory computer readable medium of clause 121, wherein calibrating the parameter of the imaging system comprises:
obtaining a signal from the sample associated with the scan;
determining a relationship between the signal and a beam profile associated with the signal; and
adjusting hardware of the imaging system to adjust the beam profile.
134. The non-transitory computer readable medium of any one of clauses 121-133, wherein the replaceable reference sample is not permanently fixed to the stage of the imaging system.
135. The non-transitory computer readable medium of any one of clauses 121-134, wherein the replaceable reference sample is a first sample affixed to the stage of the imaging system.
136. The non-transitory computer readable medium of clause 135, wherein the set of instructions that is executable by at least one processor of a computing device to cause the computing device to further perform:
removing the first sample from the stage of the imaging system; and
affixing a second sample to the stage of the imaging system.
137. A non-transitory computer readable medium that stores a set of instructions that is executable by at least one processor of a computing device to cause the computing device to perform a method, the method comprising:
after a replaceable product die is affixed to a stage of an imaging system:
supplying power to one or more pins of the replaceable product die;
obtaining a first voltage contrast image of a node of the replaceable product die;
varying a control signal associated with the supplied power of one or more of the pins to cause a resistance or a capacitance of the node to be adjusted;
obtaining a second voltage contrast image of the node; and
calibrating a resistance or a capacitance data measurement based on the first voltage contrast image and the second voltage contrast image and the adjustment.
138. The non-transitory computer readable medium of clause 137, wherein the replaceable product die is not permanently fixed to the stage of the imaging system.
139. The non-transitory computer readable medium of any one of clauses 137-138, wherein the replaceable product die is a first product die affixed to the stage of the imaging system.
140. The non-transitory computer readable medium of clause 139, wherein the set of instructions that is executable by at least one processor of a computing device to cause the computing device to further perform:
removing the first product die from the stage of the imaging system; and
affixing a second product die to the stage of the imaging system.
141. A non-transitory computer readable medium that stores a set of instructions that is executable by at least one processor of a computing device to cause the computing device to perform a method for calibration, the method comprising:
after a product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.
142. The non-transitory computer readable medium of clause 141, wherein the set of instructions that is executable by at least one processor of a computing device to cause the computing device to further perform generating an image of the product die based on the scan of the product die, the image comprising the feature of the product die.
143. The non-transitory computer readable medium of clause 142, wherein calibrating the characteristic of the imaging system is based on the feature of the product die in the image.
144. The non-transitory computer readable medium of any one of clauses 141-143, wherein the characteristic of the imaging system comprises software.
145. The non-transitory computer readable medium of clause 144, wherein calibrating the characteristic of the imaging system comprises adjusting a setting of the software of the imaging system to cause an image generated by the scan of the product die to be adjusted.
146. The non-transitory computer readable medium of any one of clauses 141-143, wherein the characteristic of the imaging system comprises hardware.
147. The non-transitory computer readable medium of clause 146, wherein the calibrating the characteristic of the imaging system comprises adjusting a setting of the hardware of the imaging system to cause an image generated by the scan of the product die to be adjusted.
148. The non-transitory computer readable medium of clause 141, wherein:
the scan of the product die enables generation of a first image of a node of the product die and a second image of the node of the product die, and further comprising:
supplying power to a pin of the product die;
obtaining the first image of the node of the product die; varying a control signal associated with the power supply of the pin to cause a characteristic of the node to be adjusted;
obtaining the second image of the node; and
calibrating the characteristic of the imaging system based on the first image, the second image, and the adjusted characteristic of the node.
149. The non-transitory computer readable medium of clause 148, wherein the first image and the second image comprise grey scale images.
150. The non-transitory computer readable medium of any one of clauses 148-149, wherein the first image and the second image comprise voltage contrast images.
151. The non-transitory computer readable medium of any one of clauses 148-150, wherein the characteristic of the node comprises at least one of a resistance of the node, a capacitance of the node, or an inductance of the node.
152. The non-transitory computer readable medium of any one of clauses 148-151, wherein the characteristic of the imaging system comprises at least one of hardware or software.
153. The non-transitory computer readable medium of clause 141, wherein calibrating the characteristic of the imaging system comprises:
obtaining a signal from the product die associated with the scan;
determining a relationship between the signal and a beam profile associated with the signal; and
adjusting hardware of the imaging system to adjust the beam profile.
154. The non-transitory computer readable medium of any one of clauses 141-153, wherein the product die is not permanently fixed to the stage of the imaging system.
155. The non-transitory computer readable medium of any one of clauses 141-154, wherein the product die is a first product die affixed to the stage of the imaging system.
156. The non-transitory computer readable medium of clause 155, wherein the set of instructions that is executable by at least one processor of a computing device to cause the computing device to further perform:
removing the first product die from the stage of the imaging system; and
affixing a second product die to the stage of the imaging system.

It will be appreciated that the embodiments of the present disclosure are not limited to the exact construction that has been described above and illustrated in the accompanying drawings, and that various modifications and changes may be made without departing from the scope thereof.

1. A system comprising:
a controller including circuitry configured to cause the system to perform, after a replaceable reference sample is affixed to a stage of an imaging system:
calibrating a parameter of the imaging system based on a scan of the reference sample by the imaging system; and
after calibrating the parameter of the imaging system, scanning a sample, wherein the sample comprises a duplicate of a feature of the reference sample.

2. The system of claim 1, wherein the controller including circuitry is further configured to cause the system to perform generating an image of the sample based on the scan of the sample, the image comprising the feature of the sample.

3. The system of claim 2, wherein calibrating the parameter of the imaging system is based on the feature of the sample in the image.

4. The system of claim 1, wherein the parameter of the imaging system comprises software.

5. The system of claim 4, wherein calibrating the parameter of the imaging system comprises adjusting a setting of the software of the imaging system to cause an image generated by the scan of the sample to be adjusted.

6. The system of claim 1, wherein the calibrating the parameter of the imaging system comprises adjusting a setting of hardware of the imaging system to cause an image generated by the scan of the sample to be adjusted.

7. The system of claim 1, wherein:
the scan of the sample enables generation of a first image of a node of the sample and a second image of the node of the sample, and further comprising:
supplying power to a pin of the sample;
obtaining the first image of the node of the sample;
varying a control signal associated with the power supply of the pin to cause a characteristic of the node to be adjusted;
obtaining the second image of the node; and
calibrating the parameter of the imaging system based on the first image, the second image, and the adjusted characteristic of the node.

8. The system of claim 7, wherein the first image and the second image comprise grey scale images.

9. The system of claim 7, wherein the first image and the second image comprise voltage contrast images.

10. The system of claim 7, wherein the parameter of the node comprises at least one of a resistance of the node, a capacitance of the node, or an inductance of the node.

11. The system of claim 1, wherein calibrating the parameter of the imaging system comprises:
obtaining a signal from the sample associated with the scan;
determining a relationship between the signal and a beam profile associated with the signal; and
adjusting hardware of the imaging system to adjust the beam profile.

12. The system of claim 1, wherein the replaceable reference sample is not permanently fixed to the stage of the imaging system.

13. The system of claim 1, wherein the replaceable reference sample is a first sample affixed to the stage of the imaging system.

14. The system of claim 13, wherein the controller including circuitry is further configured to cause the system to perform:
removing the first sample from the stage of the imaging system; and
affixing a second sample to the stage of the imaging system.

15. A non-transitory computer readable medium that stores a set of instructions that is executable by at least one processor of a computing device to cause the computing device to perform a method for calibration, the method comprising:
after a replaceable product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.

1. A system comprising:
a controller including circuitry configured to cause the system to perform, after a replaceable reference sample is affixed to a stage of an imaging system:
calibrating a parameter of the imaging system based on a scan of the reference sample by the imaging system; and
after calibrating the parameter of the imaging system, scanning a sample, wherein the sample comprises a duplicate of a feature of the reference sample.

2. The system of claim 1, wherein the controller including circuitry is further configured to cause the system to perform generating an image of the sample based on the scan of the sample, the image comprising the feature of the sample.

3. The system of claim 2, wherein calibrating the parameter of the imaging system is based on the feature of the sample in the image.

4. The system of claim 1, wherein the parameter of the imaging system comprises software.

5. The system of claim 4, wherein calibrating the parameter of the imaging system comprises adjusting a setting of the software of the imaging system to cause an image generated by the scan of the sample to be adjusted.

6. The system of claim 1, wherein calibrating the parameter of the imaging system comprises adjusting a setting of hardware of the imaging system to cause an image generated by the scan of the sample to be adjusted.

7. The system of claim 1, wherein:
the scan of the sample enables generation of a first image of a node of the sample and a second image of the node of the sample, and further comprising:
supplying power to a pin of the sample;
obtaining the first image of the node of the sample;
varying a control signal associated with the power supply of the pin to cause a characteristic of the node to be adjusted;
obtaining the second image of the node; and
calibrating the parameter of the imaging system based on the first image, the second image, and the adjusted characteristic of the node.

8. The system of claim 7, wherein the first image and the second image comprise grey scale images.

9. The system of claim 7, wherein the first image and the second image comprise voltage contrast images.

10. The system of claim 7, wherein the parameter of the node comprises at least one of a resistance of the node, a capacitance of the node, or an inductance of the node.

11. The system of claim 1, wherein calibrating the parameter of the imaging system comprises:
obtaining a signal from the sample associated with the scan;
determining a relationship between the signal and a beam profile associated with the signal; and
adjusting hardware of the imaging system to adjust the beam profile.

12. The system of claim 1, wherein the replaceable reference sample is not permanently fixed to the stage of the imaging system.

13. The system of claim 1, wherein the replaceable reference sample is a first sample affixed to the stage of the imaging system.

14. The system of claim 13, wherein the controller including circuitry is further configured to cause the system to perform:
removing the first sample from the stage of the imaging system; and
affixing a second sample to the stage of the imaging system.

15. A non-transitory computer readable medium that stores a set of instructions that is executable by at least one processor of a computing device to cause the computing device to perform operations for calibration, the operations comprising:
after a replaceable product die is affixed to a stage of an imaging system:
calibrating a characteristic of the imaging system based on a scan of the product die by the imaging system; and
after calibrating the characteristic of the imaging system, scanning a wafer,
wherein the wafer comprises a copy of a feature of the product die.

16. The non-transitory computer readable medium of claim 15, wherein operations further comprise generating an image of the product die based on the scan of the product die, the image comprising the feature of the product die.

17. The non-transitory computer readable medium of claim 16, wherein calibrating the characteristic of the imaging system is based on the feature of the product die in the image.

18. The non-transitory computer readable medium of claim 15, wherein the characteristic of the imaging system comprises software.

19. The non-transitory computer readable medium of claim 18, wherein calibrating the characteristic of the imaging system comprises adjusting a setting of the software of the imaging system to cause an image generated by the scan of the product die to be adjusted.

20. A method of calibration comprising:
after a replaceable product die is affixed to a stage of an imaging system:
calibrating a characteristic of the imaging system based on a scan of the product die by the imaging system; and
after calibrating the characteristic of the imaging system, scanning a wafer, wherein the wafer comprises a copy of a feature of the product die.
